(19) United States
(12) Patent Application Publication
(10) Pub. No.: US 2025/0003058 A1
(43) Pub. Date: Jan. 2, 2025

(54) SELECTIVE DEPOSITION OF RUTHENIUM FILM BY UTILIZING Ru(I) PRECURSORS

(71) Applicant: Merck Patent GmbH, Darmstadt (DE)

(72) Inventors: Po-Chun LIU, Kaohsiung (TW); Bhushan ZOPE, San Jose, CA (US)

(21) Appl. No.: 18/554,866

(22) PCT Filed: May 17, 2022
(86) PCT No.: PCT/EP2022/063246

§ 371 Date: Oct. 11, 2023

Related U.S. Application Data
(60) Provisional application No. 63/190,444, filed on May 19, 2021.

(51) Int. Cl. C23C 16/04; C23C 16/02; C23C 16/18; C23C 16/455

(52) U.S. Cl. CPC C23C 16/042; C23C 16/0254; C23C 16/18; C23C 16/45553

(57) ABSTRACT

The disclosed and claimed subject matter relates to the use of Ru(I) precursors in ALD or ALD-like processes for the selective deposition of Ru films.

### BACKGROUND

### Field

The disclosed and claimed subject matter relates to the use of Ru(I) precursors for use in atomic layer deposition (ALD) and ALD-like processes for selective Ru-containing film growth on at least one substrate.

### Related Art

Thin films, and in particular, thin metal-containing films, have a variety of important applications, such as in nanotechnology and the fabrication of semiconductor devices. Examples of such applications include high-refractive index optical coatings, corrosion-protection coatings, photocatalytic self-cleaning glass coatings, biocompatible coatings, dielectric capacitor layers and gate dielectric insulating films in field-effect transistors (FETs), capacitor electrodes, gate electrodes, adhesive diffusion barriers, and integrated circuits. Metallic thin films and dielectric thin films are also used in microelectronics applications, such as the high-x dielectric oxide for dynamic random-access memory (DRAM) applications and the ferroelectric perovskites used in infrared detectors and non-volatile ferroelectric random-access memories (NV-FeRAMs).

Various precursors may be used to form metal-containing thin films and a variety of deposition techniques can be employed. Such techniques include reactive sputtering, ion-assisted deposition, sol-gel deposition, chemical vapor deposition (CVD) (also known as metalorganic CVD or MOCVD), and atomic layer deposition (ALD) (also known as atomic layer epitaxy). CVD and ALD processes are increasingly used as they have the advantages of enhanced compositional control, high film uniformity, and effective control of doping.

Conventional CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is also a method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor is then passed over the substrate surface and reacts with the first precursor, forming a second monolayer of film over the first-formed monolayer of film on the substrate surface. This cycle is repeated to create a film of desired thickness.

For conventional chemical vapor deposition (CVD) process, the precursor and co-reactant are introduced into a deposition chamber via vapor phase to deposit a thick film on the substrate. On other hand, atomic layer deposition (ALD) or ALD-like process, the precursor and co-reactant are introduced into a deposition chamber sequentially, thus allowing a surface-controlled layer-by-layer deposition and importantly self-limiting surface reactions to achieve atomic-level growth of thin film. The key to a successful ALD deposition process is to employ a precursor to devise a reaction scheme consisting of a sequence of discrete, self-limiting adsorption and reaction steps. One great advantage of the ALD process is to provide much higher conformality for substrates having high aspect ratio such as >8 than CVD.

However, the continual decrease in the size of microelectronic components, such as semi-conductor devices, presents several technical challenges and has increased the need for improved thin film technologies. In particular, microelectronic components may include features on or in a substrate, which require filling, e.g., to form a conductive pathway or to form interconnections. Filling such features, especially in smaller and smaller microelectronic components, can be challenging because the features can become increasingly thin or narrow. Consequently, a complete filling of the feature, e.g., via ALD, would require infinitely long cycle times as the thickness of the feature approaches zero. Moreover, once the thickness of the feature becomes narrower than the size of a molecule of a precursor, the feature cannot be completely filled. As a result, a hollow seam can remain in a middle portion of the feature when ALD is performed. The presence of such hollow seams within a feature is undesirable because they can lead to failure of the device. Accordingly, there exists significant interest in the development of thin film deposition methods, particularly ALD methods that can selectively grow a film on one or more substrates and achieve improved filling of a feature on or in a substrate, including depositing a metal-containing film in a manner which substantially fills a feature without any voids.

As alluded to above, in conventional semiconductor device fabrication, patterning is a “top-down” process based largely on photolithography and etching, which is a main bottleneck for device downscaling. In contrast, area selective deposition (e.g., CVD and ALD) provides an alternative “bottom-up” method for patterning for advanced semiconductor manufacturing where a metal layer (e.g., Ru) is grown on bottom metal surface (e.g., Ru and TiN) proximate to the passivated dielectric substrate, but not on a dielectric (e.g., SiO₂) sidewall. See, e.g., FIG. 1. It is also desirable that these processes be oxygen free and/or have lower resistivity.

For the fabrication of future advanced nodes, processes are needed to selectively grow Ru on the bottom metal surface of recessed features (i.e., where the sidewall of recessed feature is a dielectric layer surfaces such as SiO₂ and Si₃N₄ and the bottom metal surface is Ru or TiN). Some processes, with varying degrees of success, are known but suffer from drawbacks that make them unsuitable for advanced processes. In general, only dodecacarbonyl ruthenium (DCR) is capable of growing an Ru film by oxygen-free process but it suffers from several significant drawbacks (i.e., the stability of DCR is low at higher temperature; the Ru(0) centers of DCR are only supported by CO which leads to decomposition at higher temperatures; DCR needs CO as carrier gas; and CVD Ru deposited by DCR results in the gap fill issue for narrow via and trench).

For example, U.S. Pat. No. 10,014,213 describes selectively growing Ru on a bottom metal surface involves first treating the dielectric surface with silane-type reactant to generate hydrophobic surface. The Ru then can then be grown on the bottom metal surface by vapor phase deposition. The silane-type reactant disclosed in the method includes (dimethylamino)trimethylsilane (DMATMS) and the Ru precursors used include DCR, Ru(DMPD)EtCp, Ru(DMPD)MeCp and Ru(DMPD)₂. However, DCR is a labile Ru(0) precursor which causes process issues by generating CO and/or CO₂ byproducts. In contrast, Ru(DMPD)EtCp, Ru(DMPD)MeCp and Ru(DMPD)₂ are inert Ru(II) complexes. Aside from there being no actual embodiments enabling how to use these Ru(II) precursors, it is well-established that use of these precursors requires reaction with an oxygen source in order to generate Ru films. Doing so is highly disfavored in advanced processes due to the possibility of oxidizing the underlayer.

U.S. Pat. No. 8,178,439 describes a method to selectively grow Ru capping layer on metal surface (Ru) of planarized substrate, but not on DMATMS pretreated dielectric surfaces (SiO₂). The Ru precursor used in this patent is DCR (Ru(0)). Unlike the process disclosed and claimed herein, however, the method described in U.S. Pat. No. 8,178,439 requires growing an Ru capping layer on “planarized substrate” as opposed to an Ru layer on the bottom of a via or trench. U.S. Pat. Nos. 8,242,019 and 10,378,105 describe similarly deficient methodologies. As discussed below, DCR is a labile Ru(0) precursor that is unsuitable for selective deposition processes due to the formation CO and CO₂ byproducts during its use.

Considering the above, there is a clear lack of suitable Ru precursors for atomic layer deposition (ALD) and ALD-like processes for selective Ru-containing film growth. DCR is a Ru(O) compound, while Ru(DMPD)EtCp, Ru(DMPD)MeCp and Ru(DMPD)₂ are Ru(II) compounds. It is well known that the lower oxidation state Ru(O) compound DCR results in the lability of complex. The lability of DCR results in the formation of CO and CO₂ byproducts which may damage the underlayer substrate during the process. Moreover, the lability of DCR suggests that it can only be used for CVD reaction, which may cause step coverage issues for advanced node.

Given the disadvantages of Ru(O) compounds, it thus appears preferable to select Ru compounds with higher oxidation states (i.e., I, II and III) to enhance the stability of selective deposition process. It has yet to reported, however, that Ru(II) precursors (e.g., Ru(DMPD)EtCp, Ru(DMPD)MeCp and Ru(DMPD)₂) can be used for atomic layer deposition (ALD) and ALD-like processes for selective Ru-containing film growth. Indeed, there do not appear to be any other Ru precursor with oxidation state I, II and III even mentioned in the known art for these types of selective deposition processes.

The disclosed and claimed subject matter presents the first example of Ru(I) precursor being successfully used for selective ALD of an Ru film.

### SUMMARY

In one aspect, the disclosed and claimed subject matter relates to atomic layer deposition (ALD) and ALD-like processes for selective Ru-containing film growth that includes, consists essentially of or consists of the steps of (i) passivating a dielectric material by pretreating the surface of the dielectric substrate, such as an Si-containing substrate (e.g., SiO2), with a surface conversion material (e.g., DMATMS or similar material) to convert potentially reactive surface groups (e.g., —OH groups) into non-reactive/less reactive groups (e.g., hydrophobic —CH₃ groups) and thereafter (ii) selectively depositing an Ru-containing layer on a metal (e.g., Ru, TiN, W) substrate surface located proximate to the passivated dielectric substrate, but not on the dielectric substrate surface using an Ru(I) precursor in combination with a co-reactant (e.g., H₂).

In a further aspect, the Ru(I) precursor used in the disclosed and claimed process includes a ruthenium pyrazolate precursor of Formula 1:

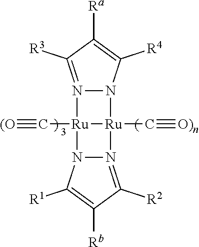

where
R¹, R², R³ and R⁴ are each independently selected from the group of H, a substituted or unsubstituted C₁ to C₂₀ linear, cyclic or branched alkyl and a substituted or unsubstituted C₁ to C₂₀ linear or branched or cyclic halogenated alkyl,
R^{a} and R^{b} are each independently selected from the group of H, a substituted or unsubstituted C₁ to C₂₀ linear, cyclic or branched alkyl and a substituted or unsubstituted C₁ to C₂₀ linear or branched or cyclic halogenated alkyl, and
n=2 or 3.

The Ru-Pz precursor is a member of the class of compounds covered by Formula 1. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃. In another aspect of this embodiment, R^{a} and R^{b} are each independently one of —CH₃, —CH₂CH₃, —CH₂CH₂CH₃, —CH(CH₃)₂, —CH₂CH(CH₃)₂ and —C(CH₃)₃. In another aspect of this embodiment, R^{a} and R^{b} are each independently H. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃ and R^{a} and R^{b} are each independently H. In another aspect of this embodiment, one or more of R¹, R², R³ and R⁴ is sterically bulky group (e.g., t-butyl groups). In another aspect of this embodiment, one or more of R, R², R³ and R⁴ is each independently one of —CF₃, —CF₂CF₃, —CF₂CF₂CF₃, —CF(CF₃)₂, —C(CF₃)₃, and any substituted or unsubstituted C₁ to C₈ perfluorinated alkyl. In another aspect of this embodiment, each of R¹ and R⁴ are the same group. In another aspect of this embodiment, each of R² and R³ are the same group. In another aspect of this embodiment, each of R¹, R², R³ and R⁴ is the same group. In one aspect of this embodiment, n=2. In one aspect of this embodiment, n=3. In one aspect of this embodiment, none of R¹, R², R³ and R⁴ are H. In one aspect of this embodiment, each of R¹, R², R³, R⁴ R¹, R^{a} and R^{b} are H.

In a further aspect, the Ru(I) precursor used in the disclosed and claimed process includes a ruthenium pyrazolate precursor having the following structure:

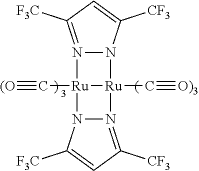

(herein “Ru-Pz 1” and/or “RuP08”).

In a further aspect, the Ru(I) precursor used in the disclosed and claimed process includes a ruthenium pyrazolate precursor having the following structure:

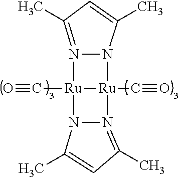

(herein “Ru-Pz 2”).

In a further aspect, the Ru(I) precursor used in the disclosed and claimed process includes a ruthenium pyrazolate precursor having the following structure:

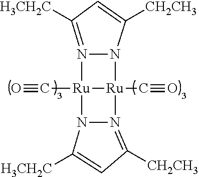

(herein “Ru-Pz 3”).

In a further aspect, the Ru(I) precursor used in the disclosed and claimed process includes a ruthenium pyrazolate precursor having the following structure:

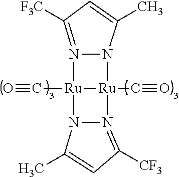

(herein “Ru-Pz 4”).

In a further aspect, the Ru(I) precursor used in the disclosed and claimed process includes a ruthenium pyrazolate precursor having the following structure:

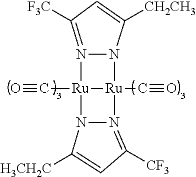

(herein “Ru-Pz 5”).

In a further aspect, the Ru(I) precursor used in the disclosed and claimed process includes a ruthenium pyrazolate precursor having the following structure:

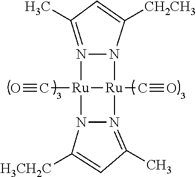

(herein “Ru-Pz 6” and/or “RuP10”).

Without being bound by theory, the positive charge of Ru(I) core reduces the lability of coordinated CO groups and ligands, which enhances the stability of deposition process. Compared with Ru (O) precursors (e.g., DCR), the inert character of the Ru(I) precursors indicate the capability of growing Ru films in ALD mode for future node.

In another aspect the disclosed and claimed subject matter relates to films grown from the disclosed and claimed process. In another aspect, the disclosed and claimed subject matter relates to the use of a Ru (I) precursor in ALD or ALD-like processes for selectively depositing a Ru-containing film on a metal substrate disposed proximate to a passivated dielectric material. In one embodiment of this aspect, the Ru(I) precursor comprises a ruthenium pyrazolate precursor disclosed above.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the target of selective deposition processes;

FIG. 2 illustrates the effect of passivation on Ru-film thickness grown from Ru(I) precursors on various substrates;

FIG. 3 illustrates the effects passivation has on Ru-film growth (cycles) grown from Ru(I) precursors;

FIG. 4 illustrates the effect of passivation on Ru-film thickness grown from Ru(II) precursors on various substrates; and

FIG. 5 illustrates the effect of passivation on Ru-film thickness grown from Ru(I) precursors on Si₃N₄.

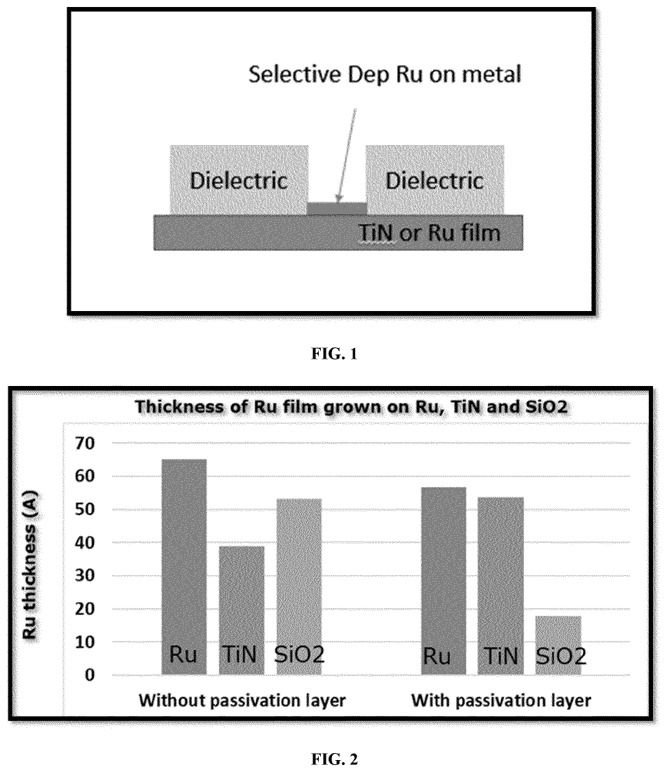

### DEFINITIONS

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp. 1-36.

Throughout the description, the terms “ALD or ALD-like” or “ALD and ALD-like” refer to a process including, but not limited to, the following process steps: (i) sequentially introducing each reactant, including the Ru-Pz precursors (ia) and co-reactant (ib), into a reactor such as a single wafer ALD reactor, semi-batch ALD reactor, or batch furnace ALD reactor; (ii) exposing a substrate to each reactant, including the Ru-Pz precursors (iia) and the co-reactant (iib), by moving or rotating the substrate to different sections of the reactor where each section is separated by inert gas curtain, i.e., spatial ALD reactor or roll to roll ALD reactor. A typical cycle of an ALD or ALD-like process includes at least steps (i) and (ii) as aforementioned.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., +10%, +5%), whichever is greater.

The disclosed and claimed precursors are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably 100 ppm measured by proton NMR or Karl Fischer titration.

The disclosed and claimed precursors are also preferably substantially free of metal ions or metals such as, Li⁺ (Li), Na⁺ (Na), K⁺ (K), Mg²⁺ (Mg), Ca²⁺ (Ca), Al³⁺ (Al), Fe²⁺ (Fe), Fe³⁺ (Fe), Ni²⁺ (Fe), Cr³⁺ (Cr), titanium (Ti), vanadium (V), manganese (Mn), cobalt (Co), nickel (Ni), copper (Cu) or zinc (Zn). These metal ions or metals are potentially present from the starting materials/reactor employed to synthesize the precursors. As used herein, the term “substantially free” as it relates to Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS.

Unless otherwise indicated, “alkyl” refers to a C₁ to C₂₀ hydrocarbon group which can be linear, branched (e.g., methyl, ethyl, propyl, isopropyl, tert-butyl and the like) or cyclic (e.g., cyclohexyl, cyclopropyl, cyclopentyl and the like). These alkyl moieties may be substituted or unsubstituted as described below. The term “alkyl” refers to such moieties with C₁ to C₂₀ carbons. It is understood that for structural reasons linear alkyls start with C₁, while branched alkyls and cyclic alkyls start with C₃. Moreover, it is further understood that moieties derived from alkyls described below, such as alkyloxy and perfluoroalkyl, have the same carbon number ranges unless otherwise indicated. If the length of the alkyl group is specified as other than described above, the above described definition of alkyl still stands with respect to it encompassing all types of alkyl moieties as described above and that the structural consideration with regards to minimum number of carbons for a given type of alkyl group still apply.

Halo or halide refers to a halogen, F, Cl, Br or I which is linked by one bond to an organic moiety. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt. % or higher, more preferably 99 wt. % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As noted above, the disclosed and claimed subject matter relates to atomic layer deposition (ALD) and ALD-like processes for selective Ru-containing film growth that includes, consists essentially of or consists of the steps of (i) passivating a dielectric material by pretreating the surface of the dielectric material with a surface conversion material and thereafter (ii) selectively depositing an Ru-containing film using an Ru(I) precursor in combination with a co-reactant.

In one embodiment, the ALD or ALD-like process for selectively depositing a Ru-containing layer or film on a metal substrate disposed proximate to a dielectric material includes the steps of:
(i) passivating the dielectric material by exposing a surface of the dielectric material with a surface conversion material; and
(ii) selectively depositing an Ru-containing layer on a surface of the metal substrate using an Ru(I) precursor in combination with a co-reactant.

In another embodiment, the ALD or ALD-like process for selectively depositing a Ru-containing layer or film on a metal substrate disposed proximate to a dielectric material consists essentially of the steps of:
(i) passivating the dielectric material by exposing a surface of the dielectric material with a surface conversion material; and
(ii) selectively depositing an Ru-containing layer on a surface of the metal substrate using an Ru(I) precursor in combination with a co-reactant.

In another embodiment, the ALD or ALD-like process for selectively depositing a Ru-containing layer or film on a metal substrate disposed proximate to a dielectric material consists of the steps of:
(i) passivating the dielectric material by exposing a surface of the dielectric material with a surface conversion material; and
(ii) selectively depositing an Ru-containing layer on a surface of the metal substrate using an Ru(I) precursor in combination with a co-reactant.

Further embodiments of the above processes, and aspects of the above-described steps, are described below.

### Step (i): Passivating the Dielectric Material

As noted above, the first step of the disclosed and claimed process includes passivating a dielectric material located proximate to a metal substrate by pretreating the surface of the dielectric substrate by exposure to a surface conversion material to render the dielectric fully or substantially inert to the deposition of Ru.

### A. Dielectric Material

In one embodiment, the dielectric substrate and/or surface of the dielectric material includes Si. In one aspect of this embodiment, the dielectric substrate and/or surface of the dielectric material includes one or more of SiO₂ and Si₃N₄. In one embodiment, the dielectric substrate and/or surface of the dielectric material includes SiO₂. In one embodiment, the dielectric substrate and/or surface of the dielectric material includes Si₃N₄.

### B. Surface Conversion Material

In one embodiment, the surface conversion material is any suitable material capable of converting potentially reactive surface groups into non-reactive/less reactive groups. In one embodiment, the surface conversion material is capable of converting a reactive —OH group into non-reactive/less reactive group. In one embodiment, the surface conversion material is capable of converting a reactive —OH group into non-reactive/less reactive hydrophobic —CH₃ group. In one embodiment, the surface conversion material includes one or more of DMATMS ((dimethylamino)trimethylsilane) and OTS (octadecyltrichlorosilane). In one embodiment, the surface conversion material includes DMATMS. In one embodiment, the surface conversion material includes OTS (octadecyltrichlorosilane).

### C. Conditions

The pretreatment step can be carried out at any suitable temperature. However, lower temperatures are generally preferred. In one embodiment, the pretreatment step is performed at a temperature in the range of about 150° C. to about 350° C. In one embodiment, the pretreatment step is performed at a temperature in the range of about 225° C. to about 325° C. In one embodiment, the pretreatment step is performed at a temperature in the range of about 200° C. to about 350° C. In one embodiment, the pretreatment step is performed at a temperature in the range of about 250° C. to about 300° C. In one embodiment, the pretreatment step is performed at a temperature in the range of about 225° C. to about 275° C. In one embodiment, the pretreatment step is performed at a temperature in the range of about 200° C. In one embodiment, the pretreatment step is performed at a temperature of about 225° C. In one embodiment, the pretreatment step is performed at a temperature of about 250° C. In one embodiment, the pretreatment step is performed at a temperature of about 275° C. In one embodiment, the pretreatment step is performed at a temperature of about 300° C. In one embodiment, the pretreatment step is performed at a temperature of about 325° C. In one embodiment, the pretreatment step is performed at a temperature of about 350° C.

When performing the pretreatment step, the pulse/purge cycle for the surface conversion material can adjusted as appropriate. In one embodiment, the pulse time is from about 0.1 to about 10 seconds. In one embodiment, the pulse time is from about 0.1 seconds to about 5 seconds. In one embodiment, the pulse time is from about 0.1 seconds to about 2 seconds. In one embodiment, the pulse time is from about 0.1 seconds to about 1 seconds. In one embodiment, the pulse time is from about 0.5 seconds to about 2 seconds. In one embodiment, the pulse time is from about 0.5 seconds to about 1 second. In one embodiment, the pulse time is from about 0.1 seconds to about 10 second. In one embodiment, the pulse time is about 0.1 seconds. In one embodiment, the pulse time is about 0.5 seconds. In one embodiment, the pulse time is about 1 second. In one embodiment, the pulse time is about 2 seconds. The purge time for any of the above embodiments is from about 0.1 seconds to about 10 seconds.

A pulse/purge cycle can be repeated for any desired number of sequences. In one embodiment, for example, the cycle can be repeated for as many cycles as desired (e.g., 50, 75, 100, 110, 120, 130, 140, 150, etc. cycles). In one embodiment, there is between 5 cycles and 300 cycles. In one embodiment, there is between 10 cycles and 250 cycles. In one embodiment, there is between 20 cycles and 200 cycles. In one embodiment, there is between 30 cycles and 150 cycles. In one embodiment, there is about 30 cycles. In one embodiment, there is about 40 cycles. In one embodiment, there is about 50 cycles. In one embodiment, there is about 75 cycles. In one embodiment, there is about 100 cycles. In one embodiment, there is about 150 cycles. In one embodiment, there is about 200 cycles. In one embodiment, there is about 250 cycles. In one embodiment, there is about 300 cycles.

The method of for pretreatment exposure can also be varied. In one embodiment, the substrate can be exposed to the surface conversion material in a continuous flow mode. In another embodiment, the substrate can be exposed to the surface conversion material in a trapping mode.

When performing the cycle, any suitable inert carrier gas can be used. In one embodiment, the carrier gas includes argon. In one embodiment, the carrier gas includes nitrogen. In one embodiment, the carrier gas includes helium. In one embodiment, the surface conversion material and carrier gas are flowed together at between about 5 sccm and about 20 sccm. In one embodiment, the surface conversion material and carrier gas are flowed together at between about 10 sccm and about 15 sccm. In one embodiment, the surface conversion material and carrier gas are flowed together at about 10 sccm. In one embodiment, the surface conversion material and carrier gas are flowed together at about 15 sccm. In one embodiment, the surface conversion material and carrier gas are flowed together at about 20 sccm.

When performing the cycle, any suitable inert purge gas can be used. In one embodiment, the purge gas includes argon. In one embodiment, the purge gas includes nitrogen. In one embodiment, the purge gas includes helium. In one embodiment, the purge gas includes one or more of argon, nitrogen and helium.

In one embodiment, the purge gas is flowed at between about 30 sccm and about 60 sccm. In one embodiment, the purge gas is flowed at between about 40 sccm and about 50 sccm. In one embodiment, the purge gas is flowed at about 30 sccm. In one embodiment, the purge gas is flowed at about 40 sccm. In one embodiment, the purge gas is flowed at about 50 sccm. In one embodiment, the purge gas is flowed at about 60 sccm.

The pretreatment step can be carried out at any suitable chamber pressure. In one embodiment, the pressure is between about 5 torr and 15 torr. In one embodiment, the pressure is between about 8 torr to about 12 torr. In one embodiment, the pressure is about 7 torr. In one embodiment, the pressure is about 8 torr. In one embodiment, the pressure is about 9 torr. In one embodiment, the pressure is about 10 torr. In one embodiment, the pressure is about 11 torr. In one embodiment, the pressure is about 12 torr. In one embodiment, the pressure is about 13 torr. In one embodiment, the pressure is about 14 torr. In one embodiment, the pressure is about 15 torr.

Step 2 (ii): Ru Film Growth

As noted above, the second step of the disclosed and claimed process includes selectively growing an Ru-containing using an Ru(I) precursor in combination with a co-reactant on a surface of a metal substrate disposed proximate to the passivated dielectric substrate.

### A. Ru(I) Precursors

As noted above, the disclosed and claimed process utilizes Ru(I) precursors. Without being bound by theory it is believed that the positive charge of Ru(I) core reduces the lability of coordinated CO groups and ligands and therefore enhances the stability of the selective deposition process.

In one embodiment, the Ru(I) precursor used in the disclosed and claimed process includes a ruthenium pyrazolate precursor of Formula 1:

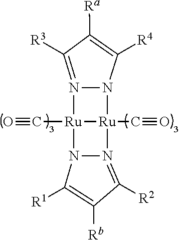

where
R¹, R², R³ and R⁴ are each independently selected from the group of H, a substituted or unsubstituted C₁ to C₂₀ linear or branched alkyl and a substituted or unsubstituted C₁ to C₂₀ linear or branched or cyclic halogenated alkyl,
R^{a} and R^{b} are each independently selected from the group of H, a substituted or unsubstituted C₁ to C₂₀ linear or branched alkyl and a substituted or unsubstituted C₁ to C₂₀ linear or branched or cyclic halogenated alkyl, and
n=2 or 3.

The Ru-Pz precursor is a member of the class of compounds covered by Formula 1. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃. In another aspect of this embodiment, R^{a} and R^{b} are each independently one of —CH₃, —CH₂CH₃, —CH₂CH₂CH₃, —CH(CH₃)₂, —CH₂CH(CH₃)₂ and —C(CH₃)₃. In another aspect of this embodiment, R^{a} and R^{b} are each independently H. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃ and R^{a} and R^{b} are each independently H. In another aspect of this embodiment, one or more of R¹, R², R³ and R⁴ is sterically bulky group (e.g., t-butyl groups). In another aspect of this embodiment, one or more of R, R², R³ and R⁴ is each independently one of —CF₃, —CF₂CF₃, —CF₂CF₂CF₃, —CF(CF₃)₂, —C(CF₃)₃, and any substituted or unsubstituted C₁ to C₈ perfluorinated alkyl. In another aspect of this embodiment, each of R¹ and R⁴ are the same group. In another aspect of this embodiment, each of R² and R³ are the same group. In another aspect of this embodiment, each of R¹, R², R³ and R⁴ is the same group. In one aspect of this embodiment, n=2. In one aspect of this embodiment, n=3. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃, R^{a} and R^{b} are each independently H, and n=2. In one aspect of this embodiment, R¹, R², R³ and R⁴ are each independently one of —CH₃, —CH₂CH₃, —CH₂CH₂CH₃, —CH(CH₃)₂, —CH₂CH(CH₃)₂ and —C(CH₃)₃, R^{a} and R^{b} are each independently H, and n=3. In one aspect of this embodiment, none of R¹, R², R³ and R⁴ are H. In one aspect of this embodiment, none of R¹, R², R³ and R⁴ are H. In one aspect of this embodiment, each of R¹, R², R³, R⁴ R¹, R^{a} and R^{b} are H. In one aspect of this embodiment, R¹, R², R³ and R⁴ are each independently one of H, —CH₃, —CH₂CH₃, —CH₂CH₂CH₃, —CH(CH₃)₂, —CH₂CH(CH₃)₂ and —C(CH₃)₃, R^{a} and R^{b} are each independently H, and n=3. In one aspect of this embodiment, R¹, R², R³ and R⁴ are each independently H, R^{a} and R^{b} are each independently H, and n=3.

In one embodiment, the Ru(I) precursor used in the disclosed and claimed process includes a ruthenium pyrazolate precursor having the following structure:

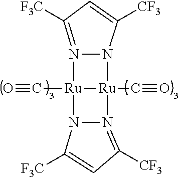

(herein “Ru-Pz 1” and/or “RuP08”).

In one embodiment, the Ru(I) precursor used in the disclosed and claimed process includes a ruthenium pyrazolate precursor having the following structure:

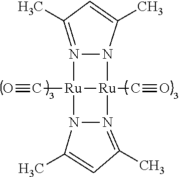

(herein “Ru-Pz 2”).

In one embodiment, the Ru(I) precursor used in the disclosed and claimed process includes a ruthenium pyrazolate precursor having the following structure:

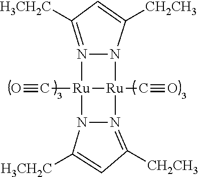

(herein “Ru-Pz 3”).

In one embodiment, the Ru(I) precursor used in the disclosed and claimed process includes a ruthenium pyrazolate precursor having the following structure:

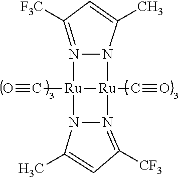

(herein “Ru-Pz 4”).

In one embodiment, the Ru(I) precursor used in the disclosed and claimed process includes a ruthenium pyrazolate precursor having the following structure:

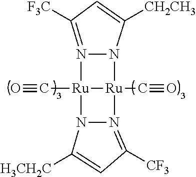

(herein “Ru-Pz 5”).

In a further aspect, the Ru(I) precursor used in the disclosed and claimed process includes a ruthenium pyrazolate precursor having the following structure:

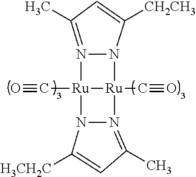

(herein “Ru-Pz 6” and/or “RuP10”).

In one embodiment, the Ru(I) precursor used in the disclosed and claimed process can include a mixture or combination of more than one of the above-described Ru(I) precursors.

### B. Co-Reactant

In one embodiment, the co-reactant is oxygen-free and includes one or more of a hydrogen co-reactant and a nitrogen-containing co-reactant. In one embodiment, the oxygen-free co-reactant includes one or more of ammonia, hydrazine, an alkylhydrazine and an alkyl amine. In one embodiment, the co-reactant includes one or more of H₂ and NH₃. In one embodiment, the co-reactant includes H₂. Applicant notes that the disclosed and claimed process can alternatively be performed using an oxygen coreactant (e.g., ozone, elemental oxygen and molecular oxygen/O₂, hydrogen peroxide and nitrous oxide) alone or in conjunction with an oxygen-free co-reactant.

### C. Metal Substrate

In one embodiment, the metal substrate includes one or more of Ru, TiN, W, Cu and Co.

In one embodiment, the metal substrate includes Ru.

In one embodiment, the metal substrate includes one or more of TiN.

In one embodiment, the metal substrate includes one or more of W.

In one embodiment, the metal substrate includes one or more of Cu.

In one embodiment, the metal substrate includes one or more of Co.

### D. Conditions

The Ru-film growing step can be carried out at any suitable temperature. However, lower temperatures are generally preferred. In one embodiment, the Ru-film growing step is performed at a temperature in the range of about 150° C. to about 350° C. In one embodiment, the Ru-film growing step is performed at a temperature in the range of about 225° C. to about 325° C. In one embodiment, the Ru-film growing step is performed at a temperature in the range of about 200° C. to about 300° C. In one embodiment, the Ru-film growing step is performed at a temperature in the range of about 250° C. to about 300° C. In one embodiment, the Ru-film growing step is performed at a temperature in the range of about 225° C. to about 275° C. In one embodiment, the Ru-film growing step is performed at a temperature of about 200° C. In one embodiment, the Ru-film growing step is performed at a temperature of about 225° C. In one embodiment, the Ru-film growing step is performed at a temperature of about 250° C. In one embodiment, the Ru-film growing step is performed at a temperature of about 275° C. In one embodiment, the Ru-film growing step is performed at a temperature of about 300° C. In one embodiment, the Ru-film growing step is performed at a temperature of about 325° C. In one embodiment, the Ru-film growing step is performed at a temperature of about 350° C.

When performing the Ru-film growing step, the Ru(I) precursor pulse time can be adjusted as appropriate. In one embodiment, the Ru(I) precursor pulse time is between about 1 second and about 20 seconds. In one embodiment, the Ru(I) precursor pulse time is between about 3 seconds and about 17 seconds. In one embodiment, the Ru(I) precursor pulse time is between about 5 seconds and about 15 seconds. In one embodiment, the Ru(I) precursor pulse time is between about 7 seconds and about 12 seconds. In one embodiment, the Ru(I) precursor pulse time is between about 5 seconds. In one embodiment, the Ru(I) precursor pulse time is about 6 seconds. In one embodiment, the Ru(I) precursor pulse time is about 7 seconds. In one embodiment, the Ru(I) precursor pulse time is about 8 seconds. In one embodiment, the Ru(I) precursor pulse time is about 9 seconds. In one embodiment, the Ru(I) precursor pulse time is about 10 seconds. In one embodiment, the Ru(I) precursor pulse time is between about 11 seconds. In one embodiment, the Ru(I) pulse time is about 12 seconds. In one embodiment, the Ru(I) precursor pulse time is about 13 seconds. In one embodiment, the Ru(I) pulse time is about 14 seconds. In one embodiment, the Ru(I) precursor pulse time is about 15 seconds.

When performing the Ru-film growing step, the co-reactant pulse time can be adjusted as appropriate. In one embodiment, the co-reactant pulse time is between about 20 seconds and about 60 seconds. In one embodiment, the co-reactant pulse time is between about 30 seconds and about 50 seconds. In one embodiment, the co-reactant pulse time is between about 35 seconds and about 45 seconds. In one embodiment, the co-reactant pulse time is between about 20 seconds. In one embodiment, the co-reactant pulse time is about 30 seconds. In one embodiment, the co-reactant pulse time is about 7 seconds. In one embodiment, the co-reactant pulse time is about 40 seconds. In one embodiment, the co-reactant pulse time is about 50 seconds. In one embodiment, the co-reactant pulse time is about 60 seconds.

When performing the Ru-film growing step, the co-reactant is flowed at between about 150 sccm and about 450 sccm. In one embodiment, the co-reactant is flowed at between about 200 sccm and about 400 sccm. In one embodiment, the co-reactant is flowed at between about 250 sccm and about 350 sccm. In one embodiment, the co-reactant is flowed at between about 275 sccm and about 325 sccm. In one embodiment, the co-reactant is flowed at about 150 sccm. In one embodiment, the co-reactant is flowed at about 200 sccm. In one embodiment, the co-reactant is flowed at about 250 sccm. In one embodiment, the co-reactant is flowed at about 300 sccm. In one embodiment, the co-reactant is flowed at about 350 sccm. In one embodiment, the co-reactant is flowed at about 400 sccm. In one embodiment, the co-reactant is flowed at about 450 sccm.

The Ru-film growing step can be carried out at any suitable chamber pressure. In one embodiment, the pressure is between about 5 torr and 15 torr. In one embodiment, the pressure is between about 8 torr to about 12 torr. In one embodiment, the pressure is about 7 torr. In one embodiment, the pressure is about 8 torr. In one embodiment, the pressure is about 9 torr. In one embodiment, the pressure is about 10 torr. In one embodiment, the pressure is about 11 torr. In one embodiment, the pressure is about 12 torr. In one embodiment, the pressure is about 13 torr. In one embodiment, the pressure is about 14 torr. In one embodiment, the pressure is about 15 torr.

Any of the Step 1 conditions described above can be combined with any of the Step 2 conditions described above. In one embodiment, step (i) and step (ii) are both performed at approximately the same temperature. In one embodiment, step (i) and step (ii) are both performed at a temperature of approximately 150° C. to approximately 350° C. In one embodiment, step (i) and step (ii) are both performed at a temperature of approximately 250° C.

### Examples

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

The RuPzl (EMD Performance Materials) were used as received without further purification. ALD experiments were performed with a CN1 ATOMIC-PREMIUM reactor. An Epsilon 3XLE spectrometer was used to analyze the thickness of Ru film grown on substrates.

### Example 1

In this example, Ru-Pz 1 (a.k.a. RuP08) was used as the Ru(I) precursor in conjunction with H₂ gas as the co-reactant to selectively deposit an Ru-film on three different substrates: Ru, TiN and SiO₂.

### Step 1: Passivation

The first step was performed using DMATMS as the surface conversion material and Ar as the carrier and purge gas. The following process condition were used:

| | |
|---|---|
| Temperature (° C.) | 250 |
| Pulse Time (DMATMS + Ar) (Sec.) | 0.5 |
| Purge Times (Ar) (Sec.) | 1 |
| Pulse Flowrate (Sccm) | 15 |
| Purge Flowrate (Sccm) | 40 |
| Cycles | 120 |
| Chamber Pressure (Torr) | 9~10 |

### Step 2: Ru Deposition

The second step was performed using Ru-Pz 1 (aka RuP08) as the Ru(I) precursor and H₂ as the co-reactant. The following process condition were used:

| | |
|---|---|
| Temperature (° C.) | 250 |
| Pulse Time (Ru-Pz 1) (Sec.) | 10 |
| Pulse Time (H₂) (Sec.) | 40 |
| H₂ Flowrate (Sccm) | 300 |
| Cycles | 30 |
| Chamber Pressure (Torr) | 10 |

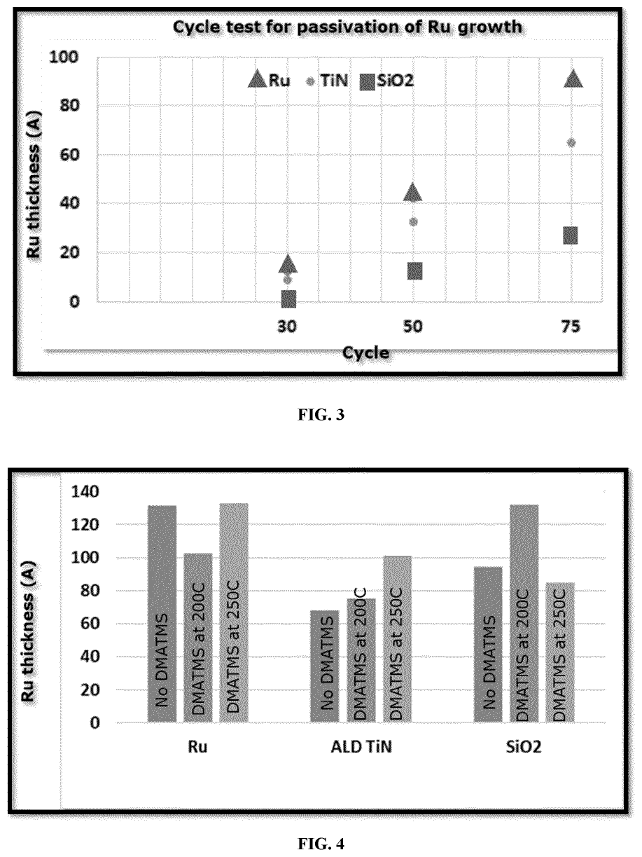

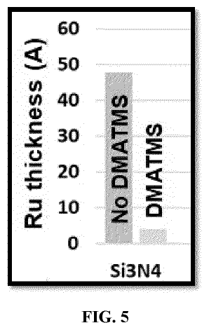

FIG. 2 and FIG. 5 each illustrate the effect of passivation on Ru-film growth from Ru(I) precursors on various substrates. FIG. 3 illustrates the process used in this example can suppress the growth of Ru on SiO₂ within 30 cycles. The data in FIG. 2, FIG. 3 and FIG. 5 collectively demonstrates that DMATMS passivates the SiO₂ and Si₃N₄ surfaces (which reduces the growth of the Ru film) and that the DMATTMS/Ru-Pz 1/H₂ utilized in this example selectively (and quickly) grows an Ru film on target Ru and TiN but not on the passivated SiO₂ and Si₃N₄.

### Comparative Example

In this comparative example, an Ru (II) precursor (i.e., RuDMBD) was used to grow an Ru-film on three different substrates: Ru, ALD TiN and SiO₂.

### Step 1: Passivation

The first step was performed using DMATMS as the surface conversion material and argon as the carrier and purge gas. The following process condition were used:

| Temperature (° C.) | 200 or 250 |
|---|---|
| Pulse Time (DMATMS + Ar) (Sec.) | 0.5 |
| Purge Times (Ar) (Sec.) | 1 |
| Pulse Flowrate (Sccm) | 15 |
| Purge Flowrate (Sccm) | 40 |
| Cycles | 120 |
| Chamber Pressure (Torr) | 9~10 |

### Step 2: Ru Deposition

The second step was performed using RuDMBD as the Ru(II) precursor and argon as the purge gas. The following process condition were used:

| | |
|---|---|
| Temperature (° C.) | 200 |
| Pulse Time (RuDMBD) (Sec.) | 0.1 |
| Purge Time (Ar) (Sec.) | 240 |
| Cycles | 30 |
| Chamber Pressure (Torr) | 1.2 |

FIG. 4 illustrates the effect passivation on Ru-film thickness grown from Ru(II) precursors on various substrates. As can be seen in FIG. 4, using DMATMS to passivate the SiO₂ does not reduce the growth of an Ru film grown from RuDMBD. Thus, the passivation step does not result in selective deposition of Ru.

### SUMMARY

It has been demonstrated that passivation (e.g., with DMATMS) is not broadly applicable for all Ru-precursors (e.g., Ru(II) precursors such as RuDMBD) and therefore cannot predictively facilitate selective Ru deposition. In addition, it has been shown for the first time that Ru(I) precursors can be used for selective deposition (e.g., Ru-Pz 1/Ru—P08).

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. An ALD or ALD-like process for selectively depositing a Ru-containing layer or film on a metal substrate disposed proximate to a dielectric material comprising the steps of:
(i) passivating the dielectric material by exposing a surface of the dielectric material with a surface conversion material; and
(ii) selectively depositing an Ru-containing layer on a surface of the metal substrate using an Ru(I) precursor in combination with a co-reactant.

2. (canceled)

3. (canceled)

4. The process of claim 1, wherein the dielectric material comprises Si.

5-7. (canceled)

8. The process of claim 1, wherein the surface conversion material converts an —OH group to a less reactive or non-reactive group.

9. (canceled)

10. The process of claim 1, wherein the surface conversion material comprises one or more of DMATMS and OTS.

11-15. (canceled)

16. The process of claim 1, wherein step (i) is performed at a temperature in the range of approximately 150° C. to approximately 350° C.

17-23. (canceled)

24. The process of claim 1, wherein step (i) comprises pulsing the surface conversion material from about 0.1 seconds to about 10 seconds.

25-59. (canceled)

60. The process of claim 1, wherein the Ru(I) precursor comprises a ruthenium pyrazolate precursor of Formula 1: 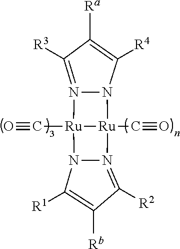
wherein
R¹, R², R³ and R⁴ are each independently selected from the group of H, a substituted or unsubstituted C₁ to C₂₀ linear, cyclic or branched alkyl and a substituted or unsubstituted C₁ to C₂₀ linear or branched or cyclic halogenated alkyl,
R^{a} and R^{b} are each independently selected from the group of H, a substituted or unsubstituted C₁ to C₂₀ linear, cyclic or branched alkyl and a substituted or unsubstituted C₁ to C₂₀ linear or branched or cyclic halogenated alkyl, and
n=2 or 3.

61-63. (canceled)

64. The process of claim 1, wherein the Ru(I) precursor comprises a ruthenium pyrazolate precursor of Formula 1: 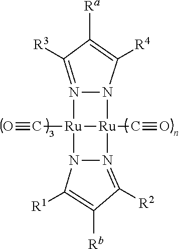
wherein
R¹, R², R³ and R⁴ are each independently one of —CH₃, —CF₃, —CH₂CH₃, CH₂CH₂CH₃, —CH(CH₃)₂, —CH₂CH(CH₃)₂ and —C(CH₃)₃;
R^{a} and R^{b} are each H, and
n=3.

65. The process of claim 1, wherein the Ru(I) precursor comprises one or more ruthenium pyrazolate precursor selected from the group of:

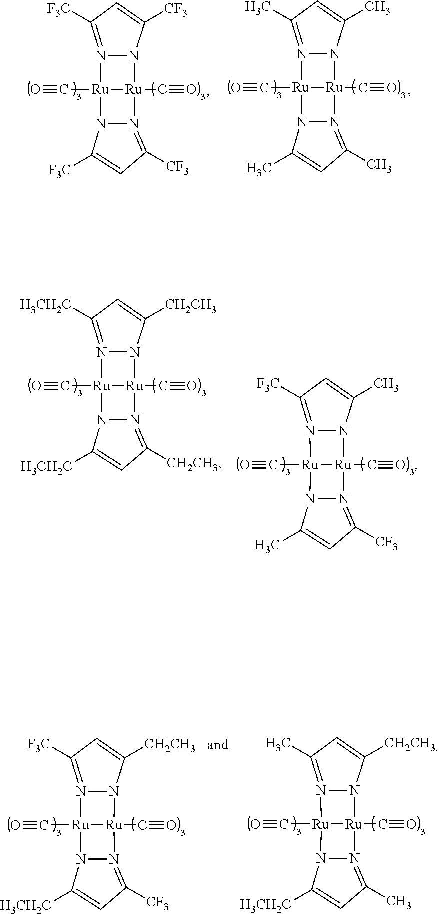

66-70. (canceled)

71. The process of claim 1, wherein the co-reactant comprises one or more of H₂ and NH₃.

72. (canceled)

73. (canceled)

74. The process of claim 1, wherein the metal substrate comprises one or more of Ru, TiN, W, Cu and Co.

75-79. (canceled)

80. The process of claim 1, wherein step (ii) is performed at a temperature in the range of approximately 150° C. to approximately 350° C.

81-87. (canceled)

88. The process of claim 1, wherein step (ii) is conducted at a pressure between about 5 torr and about 15 torr.

89-94. (canceled)

95. The process of claim 1, wherein the process is conducted with an Ru(I) precursor pulse time of between about 1 second and about 20 seconds.

96-103. (canceled)

104. The process of claim 1, wherein the process is conducted with a co-reactant pulse time between about 20 seconds and about 60 seconds.

105-121. (canceled)

122. The process of claim 1, wherein step (i) and step (ii) are both performed at approximately the same temperature.

123-127. (canceled)
